(19) United States
(12) Patent Application Publication
(10) Pub. No.: US 2026/0293740 A1
(43) Pub. Date: Sep. 24, 2026

(54) ADHESIVE COMPOSITION, CONNECTION STRUCTURE, AND METHOD FOR PRODUCING CONNECTION STRUCTURE

(71) Applicant: Resonac Corporation, Tokyo (JP)

(72) Inventors: Takahiro FUKUTOMI, Tokyo (JP); Yuka ITOH, Tokyo (JP); Yukino FUKUDA, Tokyo (JP)

(21) Appl. No.: 19/479,772

(22) PCT Filed: Oct. 21, 2024
(86) PCT No.: PCT/JP2024/037443

§ 371 Date: Oct. 29, 2025

(30) Foreign Application Priority Data
Oct. 24, 2023 (JP) 2023-182673

(51) Int. Cl. H10W 72/40; C09J 9/00; C09J 133/10; H10W 72/00; H10W 90/00; H10W 90/26

(52) U.S. Cl. CPC H10W 72/40; C09J 9/00; C09J 133/10; H10W 72/074; H10W 90/26; H10W 90/701

(57) ABSTRACT

An object of the present invention is to provide an adhesive composition capable of forming an anisotropic conductive film with which connection resistance between electrodes can be controlled to be low. The present invention is an adhesive composition having a difference between a cure onset temperature and a final cure temperature of 20° C. or less.

### TECHNICAL FIELD

The present invention relates to an adhesive composition, a connection structure, and a method for producing a connection structure.

### BACKGROUND ART

In the field of devices such as semiconductors, liquid crystal displays, smartphones, personal computers, earphones, smart watches, and wearable devices, anisotropic conductive films are used to, for example, secure electronic components or connect circuits. An anisotropic conductive film is made of, for example, an adhesive film and conductive particles dispersed therein. Patent Literature 1, for example, discloses an anisotropic conductive film in which conductive particles are dispersed in an insulating adhesive composition including a (meth)acrylate-based monomer composition, a radical polymerization initiator, and a film-forming resin; in this anisotropic conductive film, the (meth)acrylate-based monomer composition contains a (meth)acrylate-based monomer containing a cyclic ester residue or a cyclic amide residue.

When an anisotropic conductive film is placed between opposing electronic members and subjected to thermocompression bonding, an adhesive component in the anisotropic conductive film can melt to flow, which can cause the conductive particles to be trapped between opposing electrodes, and, consequently, the opposing electrodes can be electrically connected to each other. In this process, the adhesive component that has melted and flowed fills spaces, such as a space between adjacent conductive particles and a space between adjacent electrodes within each of the electronic members, and cures therein, and, accordingly, the electronic members can be bonded and secured to each other while insulation between adjacent electrodes within each of the electronic members is maintained.

### CITATION LIST

### Patent Literature

PTL 1: Japanese Unexamined Patent Application Publication No. 2010-242101

### SUMMARY OF INVENTION

### Technical Problem

Recent years have seen advances in functionality enhancement, miniaturization, and thinning of micro-OLED-equipped devices that are used in AR/VR applications. In these devices, low-heat-resistance members, such as a micro-OLED, are positioned near a mounting area in which an anisotropic conductive film is used, and, therefore, it is not desirable to perform thermocompression bonding at a high temperature for the mounting operation. Accordingly, it is necessary to use an anisotropic conductive film capable of curing at a low temperature (e.g., 130° C. or less).

However, in the case where an anisotropic conductive film that can be cured at a low temperature is used, a problem becomes manifest; that is, a residue of the adhesive component may be left between an electrode and the conductive particles. Specifically, if thermocompression bonding is performed at a low temperature for the mounting operation, the curing progresses without a sufficient flow of the adhesive component in the anisotropic conductive film, and, consequently, a residue of the adhesive component may be left between an electrode and the conductive particles and may increase connection resistance between electrodes.

Accordingly, an object of one aspect of the present invention is to provide an adhesive composition capable of forming an anisotropic conductive film with which connection resistance between electrodes can be controlled to be low.

### Solution to Problem

A final cure temperature of an adhesive composition is suitably selected such that the curing of the adhesive composition is completed in accordance with the temperature for thermocompression bonding. Thus, in a case where thermocompression bonding is performed at a low temperature, the final cure temperature is low, and, accordingly, a cure onset temperature of the adhesive composition is also usually low, as compared to a case where thermocompression bonding is performed at a high temperature. For a suitable connection between electronic members, it is required that, during thermocompression bonding, the adhesive component flow. However, if the cure onset temperature of the adhesive composition is low, the temperature range within which the adhesive component can flow (a temperature range less than the cure onset temperature) is narrow. Consequently, the time during which the adhesive component can flow is shortened, which increases the likelihood that the flow will become insufficient; this problem becomes manifest in the case where thermocompression bonding is performed at a low temperature. The present inventors diligently conducted studies and, consequently, made the following discovery. In a case where the difference between the cure onset temperature and the final cure temperature of an adhesive composition is reduced, the temperature range within which the adhesive component can flow before the curing of the adhesive composition (a temperature range less than the cure onset temperature) is relatively increased, and, therefore, the time during which the adhesive component can flow can be extended; as a result, the likelihood that a residue of the adhesive component is left between an electrode and the conductive particles is reduced, and, therefore, connection resistance between electrodes can be controlled to be low.

In some aspects, the present invention provides [1] to [8] below.

[1] An adhesive composition having a difference between a cure onset temperature and a final cure temperature of 20° C. or less.

[2] The adhesive composition according to [1], wherein the final cure temperature is 130° C. or less.

[3] The adhesive composition according to [1] or [2], wherein the cure onset temperature is 85° C. or more.

[4] The adhesive composition according to any one of [1] to [3], including a (meth)acrylate.

[5] The adhesive composition according to any one of [1] to [4], including conductive particles.

[6] A connection structure including a first electronic member including a first electrode; a second electronic member including a second electrode; and a connection portion that is disposed between the first electronic member and the second electronic member and electrically connects the first electrode and the second electrode to each other, wherein the connection portion includes a cured product of the adhesive composition according to any one of [1] to [5].

[7] A method for producing a connection structure, the method including the steps of placing the adhesive composition according to any one of [1] to [5] between a first electronic member and a second electronic member, the first electronic member including a first electrode, the second electronic member including a second electrode; and thermocompression-bonding the first electronic member to the second electronic member with the adhesive composition interposed therebetween to electrically connect the first electrode and the second electrode to each other.

[8] The producing method according to [7], wherein the thermocompression bonding is performed at 130° C. or less.

### Advantageous Effects of Invention

One aspect of the present invention can provide an adhesive composition capable of forming an anisotropic conductive film with which connection resistance between electrodes can be controlled to be low.

### BRIEF DESCRIPTION OF DRAWINGS

FIG. 1 is a schematic cross-sectional view illustrating an embodiment of an adhesive film.

FIG. 2 is a schematic cross-sectional view illustrating another embodiment of the adhesive film.

FIG. 3 is a schematic cross-sectional view illustrating an embodiment of a connection structure.

FIG. 4 includes schematic cross-sectional views illustrating an embodiment of a method for producing a connection structure.

### DESCRIPTION OF EMBODIMENTS

Embodiments of the present invention will be described in detail below with reference to the drawings.

### <Adhesive Composition>

According to an embodiment, an adhesive composition has a difference between a cure onset temperature (Tₒₙ) and a final cure temperature (T_{off}) of 20° C. or less. The adhesive composition is a thermosetting adhesive composition that cures when heated. The Tₒₙ and the T_{off} of the adhesive composition are, respectively, a temperature at which the exothermic curing reaction of the adhesive composition begins and a temperature at which the reaction is complete. The cure onset temperature and the final cure temperature are determined by performing a DSC measurement on the adhesive composition under conditions including a heating rate of 10° C./min and a measurement temperature range of 40° C. to 250° C. The Tₒₙ is a temperature corresponding to an intersection in a peak of the obtained DSC curve, where the peak is associated with the curing reaction of the adhesive composition, and the intersection is an intersection of a tangent at an inflection point, which is located between the start of the peak in the DSC curve and the top of the peak, and an extrapolation of the baseline of the DSC curve. The T_{off} is a temperature corresponding to an intersection in the peak, where the intersection is an intersection of a tangent at an inflection point, which is located between the top of the peak and the end of the peak in the DSC curve, and an extrapolation of the baseline of the DSC curve.

A difference (T_{off}−Tₒₙ) between the Tₒₙ and the T_{off} of the adhesive composition may be 18° C. or less, 16° C. or less, 15° C. or less, or 14° C. or less. The T_{off}−Tₒₙ is more than 0° C. and may be 1° C. or more or 5° C. or more.

The cure onset temperature (Tₒₙ) may be 80° C. or more, 85° C. or more, or 87° C. or more, so that the flow of the adhesive composition before curing can be promoted. The Tₒₙ may be 120° C. or less, 110° C. or less, 105° C. or less, 103° C. or less, or 101° C. or less.

The final cure temperature (T_{off}) may be 130° C. or less, 120° C. or less, or 110° C. or less, so that a degree of conversion of the curing reaction of the adhesive composition at a low temperature (hereinafter also simply referred to as a “degree of conversion”) can be improved. The T_{off} may be 100° C. or more or 105° C. or more.

The adhesive composition may include a (meth)acrylate. Examples of the (meth)acrylate include (poly)urethane (meth)acrylate, methyl (meth)acrylate, ethyl (meth)acrylate, isopropyl (meth)acrylate, isobutyl (meth)acrylate, ethylene glycol diacrylate, diethylene glycol diacrylate, triethylene glycol diacrylate, dimethylol tricyclodecane diacrylate, trimethylolpropane triacrylate, tetramethylolmethane tetracrylate, 2-hydroxy-1,3-diacryloxypropane, 2,2-bis[4-(acryloxymethoxy)phenyl]propane, 2,2-bis[4-(acryloxypolyethoxy)phenyl]propane, dicyclopentenyl acrylate, tricyclodecanyl acrylate, bis(acryloxyethyl) isocyanurate, ε-caprolactone-modified tris(acryloxyethyl) isocyanurate, tris(acryloyloxyethyl) isocyanurate, and ethylene oxide-modified phosphoric acid di(meth)acrylate.

A content of the (meth)acrylate may be 10% by mass or more, 20% by mass or more, 30% by mass or more, or 40% by mass or more and may be 80% by mass or less, 70% by mass or less, 60% by mass or less, or 50% by mass or less, based on a total mass of solids present in the adhesive composition (in the case where the adhesive composition includes conductive particles, which will be described later, the solids exclude the conductive particles present in the adhesive composition, and the solids are hereinafter also referred to as an “adhesive component”).

In the adhesive composition, only a (meth)acrylate may be included as a polymerizable material, or a different polymerizable material may be included in addition to a (meth)acrylate. The polymerizable material is a material containing a functional group that polymerizes via radicals. Examples of the different polymerizable material include maleimide compounds.

The content of the polymerizable material different from a (meth)acrylate may be 10% by mass or less, 5% by mass or less, or 1% by mass or less, based on the total mass of the adhesive component.

The adhesive composition may include a curing agent (thermal radical polymerization initiator). The curing agent is a compound that, when heated, decomposes to yield free radicals.

Examples of the curing agent include peroxides and azo compounds. Examples of the peroxides include diacyl peroxides, such as dioctanoyl peroxide, dilauroyl peroxide, distearoyl peroxide, and dibenzoyl peroxide; peroxydicarbonates, such as bis(4-t-butylcyclohexyl) peroxydicarbonate, di-2-ethoxyethyl peroxydicarbonate, and di-2-ethylhexyl peroxydicarbonate; peroxyesters, such as t-butyl peroxypivalate, t-hexyl peroxypivalate, 1,1,3,3-tetramethylbutyl peroxy-2-ethylhexanoate, 2,5-dimethyl-2,5-di(2-ethylhexanoylperoxy)hexane, t-hexyl peroxy-2-ethylhexanoate, t-butyl peroxy-2-ethylhexanoate, t-butyl peroxyisobutylate, t-hexyl peroxyisopropylmonocarbonate, t-butyl peroxy-3,5,5-trimethylhexanoate, t-butyl peroxylaurate, t-butyl peroxy-2-ethylhexyl monocarbonate, t-butyl peroxybenzoate, t-hexyl peroxybenzoate, 2,5-dimethyl-2,5-bis(benzoylperoxy)hexane, and t-butyl peroxyacetate; peroxyketals, such as 1,1-bis(t-butylperoxy)cyclohexane, 1,1-bis(t-butylperoxy)-2-methylcyclohexane, 1,1-bis(t-butylperoxy)-3,3,5-trimethylcyclohexane, 1,1-bis(t-hexylperoxy)cyclohexane, and 1,1-bis(t-hexylperoxy)-3,3,5-trimethylcyclohexane; dialkyl peroxides, such as dicumyl peroxide, t-butyl cumyl peroxide, and di-t-butyl peroxide; and hydroperoxides, such as p-menthane hydroperoxide.

Examples of the azo compounds include 2,2′-azobis(2,4-dimethylvaleronitrile) and 2,2′-azobisisobutyronitrile.

Regarding the curing agent, one of the above-mentioned peroxides and azo compounds may be used alone, or two or more of them may be used in combination. The Tₒₙ of the adhesive composition can be adjusted by the selection of which type of curing agent (or which combination of two or more curing agents if two or more curing agents are used in combination) to use. Preferably, the adhesive composition includes, as a curing agent, at least one of a diacyl peroxide and a peroxyester. The diacyl peroxide and the peroxyester may each independently have a one-minute half-life temperature of 90 to 175° C. In addition, the diacyl peroxide and the peroxyester may each independently have a molecular weight of 180 to 1000.

The content of the curing agent may be 0.05% by mass or more, 0.1% by mass or more, 1% by mass or more, or 2% by mass or more and may be 20% by mass or less, 10% by mass or less, or 8% by mass or less, based on the total mass of the adhesive component.

The adhesive composition may include a curing modifier. A curing modifier is a compound that promotes the polymerization of a radically polymerizable compound, by rapidly reacting with radicals, such as the initiating radical formed by the decomposition of the curing agent and the propagating radical formed by an attack on the radically polymerizable compound by the initiating radical, and, under heat at 60° C. or more, forming radicals again. Thus, by adding a curing modifier or by adjusting the content of a curing modifier, it is possible to adjust both the T_{off} and Tₒₙ, thereby enabling the T_{off}−Tₒₙ to be adjusted to fall within the above-mentioned range. In addition, by adding a curing modifier or by adjusting the content of a curing modifier, it is possible to adjust a flowability of the adhesive composition.

The curing modifier may be, for example, an amine compound containing a divalent organic group represented by general formula (A) below.

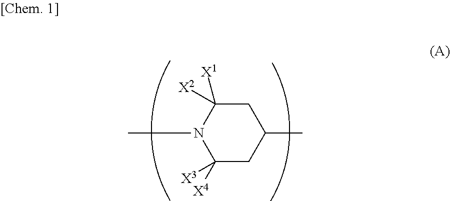

In general formula (A), X¹, X², X³, and X⁴ each independently represent a hydrogen atom or an alkyl group having 1 to 5 carbon atoms. The alkyl group is not limited to a linear alkyl group and may be a branched alkyl group or a cyclic alkyl group.

The amine compound containing a divalent organic group represented by general formula (A) may be an amine compound represented by general formula (1) below.

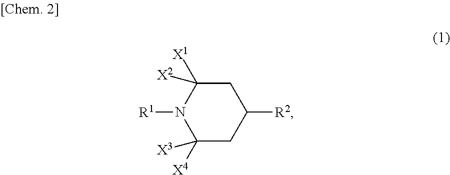

In general formula (1), R¹ and R² each independently represent a hydrogen atom, a hydroxy group, or a monovalent organic group, and X¹, X², X³, and X⁴ each independently represent a hydrogen atom or an alkyl group having 1 to 5 carbon atoms.

The organic groups are substituents containing carbon. The substituents may have any structure. The monovalent organic group that can be used as R² may be an alkyl group having 1 to 10 carbon atoms, an aryl group, an alkoxy group having 2 to 20 carbon atoms, an ether group, an ester group, or the like. Examples of the alkyl group having 1 to 10 carbon atoms include methyl groups. Examples of the alkoxy group having 2 to 20 carbon atoms include octoxy groups. The ester group can be obtained by subjecting a compound in which R² is a hydroxy group to an esterification reaction with a monocarboxylic acid (e.g., a methacrylic acid or 2-methylhexanoic acid), a dicarboxylic acid (e.g., a sebacic acid), a tetracarboxylic acid, or the like.

In general formula (1), R¹ may be a hydrogen atom, a hydroxy group, an alkyl group having 1 to 10 carbon atoms, an aryl group, an alkoxy group having 2 to 20 carbon atoms, or a monovalent organic group represented by general formula (2) below. Examples of the alkyl group having 1 to 10 carbon atoms include methyl groups. Examples of the alkoxy group having 2 to 20 carbon atoms include octoxy groups.

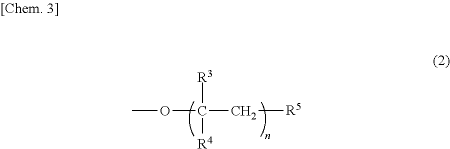

In general formula (2), R³ represents a hydrogen atom or an alkyl group having 1 to 5 carbon atoms, R⁴ represents an ester group having 1 to 5 carbon atoms, a benzyl ester group, a carboxyl group, or an aryl group, R⁵ represents a hydrogen atom, an alkyl group having 1 to 20 carbon atoms, an alkoxy group having 1 to 20 carbon atoms, a phenoxy group, an aryl group, a carbonyloxy group having 1 to 20 carbon atoms, a phenylcarbonyloxy group, or a vinyl group, and n represents an integer of 1 to 20. The phenoxy group, the aryl group, and the phenylcarbonyloxy group may be substituted with an alkyl group having 1 to 5 carbon atoms. One amine compound may be used alone, or two or more amine compounds may be used as a mixture.

Preferably, the curing modifier has one or more aminoxyl structures in the molecule. Such curing modifiers can exist as stable radicals even in the air and, therefore, have an advantage of enabling the adhesive composition to have improved storage stability.

Specific example of the compound having an aminoxyl structure include 2,2,6,6-tetramethylpiperidine 1-oxyl, 2,2-dimethyl-6-phenylpiperidine-1-oxyl, 2,2,6-trimethyl-6-phenylpiperidine-1-oxyl, 2,6-diphenylpiperidine-1-oxyl, 4-acetamide-2,2,6,6-tetramethylpiperidine-1-oxyl, 4-amino-2,2,6,6-tetramethylpiperidine-1-oxyl, 4-carboxy-2,2,6,6-tetramethylpiperidine-1-oxyl, 3-carboxy-2,2,6,6-tetramethylpiperidine-1-oxyl, 4-(2-chloroacetamide)-2,2,6,6-tetramethylpiperidine-1-oxyl, 4-hydroxy-2,2,6,6-tetramethylpiperidine-1-oxyl, 4-hydroxy-2,2,6,6-tetramethylpiperidine-1-oxylbenzoate, 4-(2-iodoacetamide)-2,2,6,6-tetramethylpiperidine-1-oxyl, 4-isothiocyanato-2,2,6,6-tetramethylpiperidine-1-oxyl, 4-isocyanato-2,2,6,6-tetramethylpiperidine-1-oxyl, 4-methoxy-2,2,6,6-tetramethylpiperidine-1-oxyl, 4-oxo-2,2,6,6-tetramethylpiperidine-1-oxyl, 2,2-dimethyl-6-cyclohexylpiperidine-1-oxyl, 2,6-dicyclohexylpiperidine-1-oxyl, 2,2-dimethyl-6-cyclopentylpiperidine-1-oxyl, 2,6-dicyclopentylpiperidine-1-oxyl, 2,2,5-trimethyl-4-phenyl-3-azahexane-3-nitrooxide, 2,2,5,5-tetramethylpyrrolidine-1-oxyl, 2,5-diphenylpyrrolidine-1-oxyl, 2,2-dimethyl-5-phenylpyrrolidine-1-oxyl, and 2,2,5-trimethyl-5-phenylpyrrolidine-1-oxyl. One compound having an aminoxyl structure may be used alone, or two or more such compounds may be used as a mixture.

The content of the curing modifier may be 0.001% by mass or more, 0.01% by mass or more, 0.05% by mass or more, or 0.07% by mass or more and may be 30% by mass or less, 20% by mass or less, 10% by mass or less, 5% by mass or less, or 1% by mass or less, based on the total mass of the adhesive component.

The adhesive composition may include a thermoplastic resin. Examples of the thermoplastic resin include polyamide resins, phenoxy resins, (meth)acrylic resins, polyimide resins, polyester resins, polyurethane resins, polyester urethane resins, and polyvinyl butyral resins. One thermoplastic resin may be used alone, or two or more thermoplastic resins may be used as a mixture.

The content of the thermoplastic resin may be 20% by mass or more and 50% by mass or less based on the total mass of the adhesive component.

The adhesive composition may further include other components, examples of which include adhesion promoters, coupling agents (e.g., silane coupling agents), ion trapping agents, visualizing agents, dispersants, photoradical polymerization initiators, and fillers. The content of the other components may be, for example, 1% by mass or more and 20% by mass or less based on the total mass of the adhesive component.

The adhesive composition may include conductive particles. The conductive particles may include a non-conductive core and a conductive layer provided on the core. It is preferable that a surface of the core be substantially entirely coated with the conductive layer; however, a portion of the surface of the core may be exposed, without being coated with the conductive layer, to the extent that the function of electrically connecting electronic members to each other is maintained.

The core is formed of a non-conductive material, such as glass, a ceramic, or a resin. Preferably, the core is formed of a resin. Examples of the resin include acrylic resins, styrenic resins, silicone resins, polybutadiene resins, and copolymers of monomers that form any of the foregoing resins. The core may be a particle including a polymer that includes, as a monomer unit, at least one monomer selected from styrene and divinylbenzene. The polymer may further include, as a monomer unit, a (meth)acrylate. The core may have an average diameter of, for example, 1 μm or more or 2 μm or more and may be 40 μm or less, 30 μm or less, or 20 μm or less.

The conductive layer is formed of, for example, Ni, Cu, Ag, Ru, Pd, or an alloy containing any of these metal elements. The alloy may be, for example, an alloy containing Ni (Ni alloy). Examples of the Ni alloy include Ni—B, Ni—P, and Ni—W—B. The conductive layer may have a thickness of, for example, 50 nm or more and 300 nm or less. The thickness of the conductive layer can be measured with an electron microscope.

The conductive layer may be made up of one, two, or three or more conductive layers. In the case where the conductive layer is made up of two conductive layers, the conductive particles may include a first conductive layer and a second conductive layer. The first conductive layer may define an outermost surface of the conductive particles, and the second conductive layer may be provided between the first conductive layer and the core. The first conductive layer may be formed of, for example, Au or Pd. The second conductive layer may be formed of, for example, Ni. The thickness of the first conductive layer may be, for example, 2 nm or more and 200 nm or less. The thickness of the second conductive layer may be, for example, 50 nm or more and 300 nm or less.

The conductive particles may have a generally spherical shape. The conductive particles may have multiple protrusions formed on a surface thereof. The multiple protrusions may be formed of one conductive layer or two conductive layers.

The conductive particles may have an average particle size of, for example, 1 μm or more and 40 μm or less. The average particle size of the conductive particles can be determined by measuring the particle size of each of ten conductive particles by SEM observation and calculating an average of the obtained ten data points.

The content of the conductive particles may be 5% by mass or more or 10% by mass or more and may be 30% by mass or less or 25% by mass or less, based on the total mass of the solids present in the adhesive composition.

The content of the conductive particles may be 0.1% by volume or more and may be 50% by volume or less or 40% by volume or less, based on a total volume of the solids present in the adhesive composition.

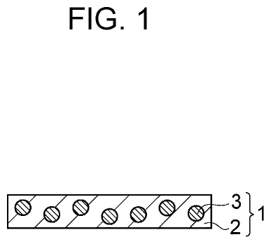

The adhesive composition may be in the form of a paste or a film. FIG. 1 is a schematic cross-sectional view illustrating an embodiment of the adhesive composition in the form of a film (adhesive film). In an embodiment, as illustrated in FIG. 1, an adhesive film 1 is formed of a single layer made up of an adhesive component (insulating adhesive) 2 and conductive particles 3, which are dispersed in the adhesive component 2.

In another embodiment, the adhesive film may have two or more regions. The adhesive film may include a first region, which includes a first adhesive component, and a second region, which is provided adjacent to the first region and includes a second adhesive component. The first region and the second region may each be a layer.

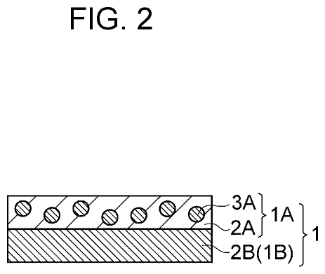

For example, as illustrated in FIG. 2, the adhesive film 1 may have a two-layer structure that includes a layer 1A, which includes conductive particles 3A, and a layer 1B, which does not include conductive particles; the layer 1A is a first adhesive layer and formed of an adhesive component 2A and the conductive particles 3A dispersed in the adhesive component 2A, and the layer 1B is a second adhesive layer and formed of an adhesive component 2B. In this case, the first adhesive layer 1A may include any of the above-mentioned materials: polymerizable materials, curing agents, curing modifiers, thermoplastic resins, conductive particles, and other components that may be included as necessary. Furthermore, the second adhesive layer 1B may include any of the above-mentioned materials: polymerizable materials, curing agents, curing modifiers, thermoplastic resins, and other components that may be included as necessary. The types of components included in the second adhesive layer 1B may be the same as or different from those in the first adhesive layer 1A.

In the first adhesive layer and the second adhesive layer, the content of each of the polymerizable material, the curing agent, the curing modifier, the thermoplastic resin, and other components may independently be similar to the content of that component in the above-described adhesive composition. In this case, the expression “based on the total mass of the adhesive component” is to be read as “based on the total mass of the adhesive component present in the first adhesive layer” or “based on the total mass of the adhesive component present in the second adhesive layer”.

In the case where the adhesive composition is in the form of a film, the Tₒₙ and the T_{off} of the adhesive composition (adhesive film) are determined by performing a DSC measurement on the entirety of the adhesive film. In the case where the adhesive film includes two or more regions, the Tₒₙ and the T_{off} are determined by performing a DSC measurement on the entirety of the adhesive film including two or more regions. For example, in a case where the Tₒₙ and the T_{off} of the adhesive film 1 illustrated in FIG. 2 are to be determined, the stack of the first adhesive layer 1A and the second adhesive layer 1B is subjected to measurement, and a DSC measurement is performed in the manner described above.

The adhesive film 1 may have a thickness of, for example, 5 μm or more or 10 μm or more and 50 μm or less, 30 μm or less, or 20 μm or less.

The adhesive composition (adhesive film 1) may be a conductive adhesive composition (conductive adhesive film) and may be an anisotropic conductive adhesive composition (anisotropic conductive adhesive film). The adhesive composition can be suitably used for the production of a connection structure.

### <Connection Structure>

According to an embodiment, a connection structure includes a first electronic member including a first electrode; a second electronic member including a second electrode; and a connection portion that is disposed between the first electronic member and the second electronic member and electrically connects the first electrode and the second electrode to each other, and the connection portion includes a cured product of the adhesive composition described above.

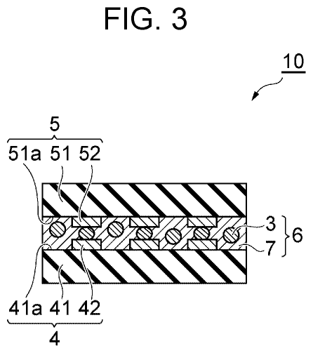

FIG. 3 is a schematic cross-sectional view illustrating the embodiment of the connection structure. As illustrated in FIG. 3, a connection structure 10 includes a first electronic member 4 and a second electronic member 5, which oppose each other, and a connection portion 6, which is disposed between the first electronic member 4 and the second electronic member 5 and connects the first electronic member 4 to the second electronic member 5.

The first electronic member 4 includes a first substrate 41 and a first electrode 42, which is formed on a main surface 41a of the first substrate 41. The second electronic member 5 includes a second substrate 51 and a second electrode 52, which is formed on a main surface 51a of the second substrate 51.

The first electronic member 4 and the second electronic member 5 may each be any component in which an electrode that requires electrical connection is formed. Examples of the component in which an electrode is formed include active elements, such as diodes (e.g., micro-OLEDs), semiconductor chips, transistors, and thyristors; passive elements, such as capacitors, resistors, and coils; and electrode-equipped substrates, such as printed circuit boards.

The first substrate 41 and the second substrate 51 may each be a silicon substrate, a glass substrate, a flexible substrate, or the like. The flexible substrate may contain, for example, at least one thermoplastic resin selected from the group consisting of polyimides (PI), polyethylene terephthalates (PET), polycarbonates (PC), and polyethylene naphthalates (PEN).

Examples of an electrode material that forms the first electrode 42 and the second electrode 52 include metals, such as Ag, Ni, Al, Au, Cu, Ti, and Mo, metal oxides, such as ITO and IZO, and conductive materials, such as silver nanowires and carbon nanotubes. The first electrode 42 and the second electrode 52 may be formed of the same material or different respective materials.

The first electronic member 4 and the second electronic member 5 may be provided with one first electrode 42 and one second electrode 52, respectively; preferably, they are provided with multiple electrodes defining predetermined spaces.

The connection portion 6 includes an insulating material 7, which is a cured product of the adhesive composition, and the conductive particles 3. The conductive particles 3 may be disposed not only between the opposing first electrode 42 and the second electrode 52 but also between the main surface 41a of the first substrate 41 and the main surface 51a of the second substrate 51. In the connection structure 10, the first electrode 42 is electrically connected to the second electrode 52 via the conductive particles 3. Specifically, some of the conductive particles 3 are in contact with both the first electrode 42 and the second electrode 52.

As described, the opposing first electrode 42 and the second electrode 52 are electrically connected to each other via the conductive particles 3, in the connection structure 10. Consequently, connection resistance between the first electrode 42 and the second electrode 52 is sufficiently reduced. Accordingly, current can flow smoothly between the first electrode 42 and the second electrode 52, and, therefore, the first electronic member 4 and the second electronic member 5 can serve their functions sufficiently.

### <Method for Producing Connection Structure>

The connection structure can be produced by a method including the following steps: placing the adhesive composition between a first electronic member and a second electronic member, the first electronic member including a first electrode, the second electronic member including a second electrode; and thermocompression-bonding the first electronic member to the second electronic member with the adhesive composition interposed therebetween to electrically connect the first electrode and the second electrode to each other.

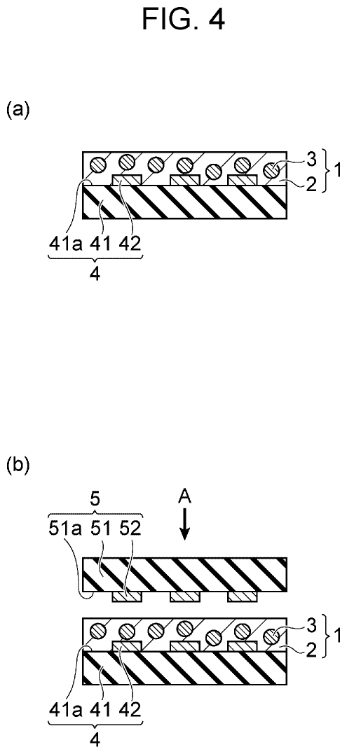

FIG. 4 includes schematic cross-sectional views illustrating an embodiment of the method for producing a connection structure. First, as illustrated in FIG. 4(a), an adhesive film 1 (adhesive composition in the form of a film) is placed on a main surface 41a of a first electronic member 4. In a case where the adhesive film 1 has been stacked on a substrate (not illustrated), the stack of the substrate and the adhesive film 1 is placed on the first electronic member 4 in a manner such that the adhesive film 1-side of the substrate faces the first electronic member 4. In a case where the adhesive film 1 includes a first adhesive layer 1A and a second adhesive layer 1B, as illustrated in FIG. 2, it is preferable, from the standpoint of improving the number of conductive particles that are trapped between the opposing electrodes, that the adhesive film 1 be placed in a manner such that the first adhesive layer 1A-side is in contact with the main surface 41a of the first electronic member 4.

After the adhesive film 1 has been placed on the main surface 41a of the first electronic member 4, pressure may be applied to the stack of the adhesive film 1 and the first electronic member 4 in a stacking direction to provisionally connect the adhesive film 1 to the first electronic member 4. In this process, heat may be applied together with pressure.

Subsequently, as illustrated in FIG. 4(b), a second electronic member 5 is placed on the adhesive film 1 that has been placed on the first electronic member 4, in a manner such that the second electrode 52-side faces the first electronic member 4 (i.e., such that the first electrode 42 and the second electrode 52 are placed in an opposing relationship, and that the adhesive film 1 is placed between the first electronic member 4 and the second electronic member 5). In a case where the adhesive film 1 has been stacked on a substrate (not illustrated), the substrate is to be removed before the second electronic member 5 is placed on the adhesive film 1.

Then, the first electronic member 4 and the second electronic member 5 are thermocompression-bonded together with the adhesive film 1 interposed therebetween. The thermocompression bonding is performed, for example, by applying heat and pressure in a direction of arrow A, illustrated in FIG. 4(b). The application of heat and pressure in the direction of arrow A causes the adhesive film 1 to cure to electrically connect the first electrode 42 and the second electrode 52 to each other. As a result, a connection structure 10, as illustrated in FIG. 3, can be obtained.

The thermocompression bonding may be performed, for example, at a pressure of 5 MPa or more and 20 MPa or less per total connection area. In addition, the thermocompression bonding may be performed at a temperature higher than the Tₒₙ of the adhesive composition (adhesive film). For example, the thermocompression bonding may be performed at 100° C. or more, and may be performed at 170° C. or less, 150° C. or less, or 130° C. or less. A pressure application time and a heating time for carrying out the thermocompression bonding may be, for example, 10 seconds or more and 60 seconds or less.

In the connection structure 10 obtained as described above, conductive particles 3 can be brought into contact with both the opposing first electrode 42 and the second electrode 52, and, therefore, connection resistance between the first electrode 42 and the second electrode 52 can be sufficiently reduced.

In the case where the application of pressure to the adhesive film 1 is performed while heat is applied thereto, the curing of an adhesive component 2 for forming an insulating material 7 can be accomplished in a state in which the distance between the first electrode 42 and the second electrode 52 is sufficiently reduced. As a result, the first electronic member 4 is firmly connected to the second electronic member 5 with the connection portion 6 interposed therebetween.

### EXAMPLES

The present invention will be described in more detail below with reference to Examples. The present invention is in no way limited to the Examples.

### <Synthesis of Polyurethane Acrylate (UA1)>

2500 parts by mass (2.50 mol) of poly(1,6-hexanediol carbonate) (trade name: Duranol T5652, manufactured by Asahi Kasei Chemicals Corporation, number average molecular weight: 1000) and 666 parts by mass (3.00 mol) of isophorone diisocyanate (manufactured by Sigma-Aldrich Corporation) were added dropwise uniformly over 3 hours to a reaction vessel, which was equipped with a stirrer, a thermometer, a reflux condenser with a calcium chloride drying tube, and a nitrogen gas inlet tube. Next, sufficient nitrogen gas was introduced into the reaction vessel, and then, the contents of the reaction vessel were heated to 70 to 75° C. to allow the reaction to proceed. Next, 0.53 parts by mass (4.3 mmol) of hydroquinone monomethyl ether (manufactured by Sigma-Aldrich Corporation) and 5.53 parts by mass (8.8 mmol) of dibutyltin dilaurate (manufactured by Sigma-Aldrich Corporation) were added to the reaction vessel, and then, 238 parts by mass (2.05 mol) of 2-hydroxyethyl acrylate (manufactured by Sigma-Aldrich Corporation) were added. The contents were reacted at 70° C. for 6 hours under an air atmosphere. Accordingly, a polyurethane acrylate (UA1) was obtained. The polyurethane acrylate (UA1) had a weight average molecular weight of 15000. The weight average molecular weight was measured on a gel permeation chromatograph (GPC) under the following conditions and using a standard curve generated from polystyrene standards.

### (Measurement Conditions)

Instrument: GPC-8020, manufactured by Tosoh Corporation
Detector: RI-8020, manufactured by Tosoh Corporation
Column: Gelpack GLA160S+GLA150S, manufactured by Hitachi Chemical Co., Ltd.
Sample Concentration: 120 mg/3 mL
Solvent: tetrahydrofuran
Injection Volume: 60 μL
Pressure: 2.94×10⁶ Pa (30 kgf/cm²)
Flow rate: 1.00 mL/min

### Comparative Example 1

### (Preparation of First Adhesive Composition)

A first adhesive composition was prepared by mixing the following ingredients: 17 parts by mass of dimethylol tricyclodecane diacrylate (product name: DCP-A, manufactured by Kyoeisha Chemical Co., Ltd.), 30 parts by mass of the polyurethane acrylate (UA1) prepared as described above, and 1.5 parts by mass of ethylene oxide-modified phosphoric acid dimethacrylate (product name: PM-21, manufactured by Nippon Kayaku Co., Ltd.), used as polymerizable materials; 2.5 parts by mass of 2,5-dimethyl-2,5-di(2-manufactured by NOF Corporation), used as a curing agent; 45 parts by mass of a polyester urethane resin (product name: UR-8200, manufactured by Toyobo Co., Ltd.), used as a thermoplastic resin; 2.8 parts by mass of 3-glycidoxypropyltrimethoxysilane (product name: SH-6040, manufactured by Dow Toray Co., Ltd.), used as a silane coupling agent; 2.5 parts by mass of Aerosil (product name: R-202, manufactured by Nippon Aerosil Co., Ltd.), used as a filler; and 26 parts by mass of conductive particles (average particle size: 3 μm) including a non-conductive core and a conductive layer provided on the core, the conductive particles having multiple protrusions formed on a surface thereof.

### (Preparation of Second Adhesive Composition)

A second adhesive composition was prepared by mixing the following ingredients: 30 parts by mass of dimethylol tricyclodecane diacrylate (product name: DCP-A, manufactured by Kyoeisha Chemical Co., Ltd.), 27.5 parts by mass of the polyurethane acrylate (UA1) prepared as described above, and 2.5 parts by mass of ethylene oxide-modified phosphoric acid dimethacrylate (product name: PM-21, manufactured by Nippon Kayaku Co., Ltd.), used as polymerizable materials; 5.0 parts by mass of 2,5-dimethyl-2,5-di(2-manufactured by NOF Corporation), used as a curing agent; 27.5 parts by mass of a polyester urethane resin (product name: UR-4800, manufactured by Toyobo Co., Ltd.) and 15 parts by mass of a phenoxy resin (product name: YP-70, manufactured by Nippon Steel Chemical & Material Co., Ltd.), used as thermoplastic resins; 5 parts by mass of 3-glycidoxypropyltrimethoxysilane (product name: SH-6040, manufactured by Dow Toray Co., Ltd.), used as a silane coupling agent; and 8 parts by mass of Aerosil (product name: R-202, manufactured by Nippon Aerosil Co., Ltd.), used as a filler.

A first adhesive layer was prepared by applying the first adhesive composition onto a substrate (PET film with a thickness of 50 μm) with an applicator. Furthermore, a second adhesive layer was prepared with the second adhesive composition in the same manner as the first adhesive layer. In addition, an adhesive film (thickness: 14 μm) was prepared by laminating the first adhesive layer on the second adhesive layer with a laminator.

### Example 1

An adhesive film was prepared as in Comparative Example 1, except that, regarding the second adhesive composition, the amount of 2,5-dimethyl-2,5-di(2-ethylhexanoylperoxy)hexane added, as a curing agent, was changed to 4.8 parts by mass, and 0.5 parts by mass of dilauroyl peroxide (product name: Peroyl L, manufactured by NOF Corporation), as a curing agent, and 0.1 parts by mass of 4-hydroxy-2,2,6,6-tetramethylpiperidine-1-oxyl (manufactured by Tokyo Chemical Industry Co., Ltd.), as a curing modifier, were further added. The content of the conductive particles was 1% by volume based on the total volume of the adhesive film.

### Example 2

An adhesive film was prepared as in Example 1, except that, regarding the second adhesive composition, the amount of 2,5-dimethyl-2,5-di(2-ethylhexanoylperoxy)hexane added, as a curing agent, was changed to 4.5 parts by mass, and the amount of dilauroyl peroxide added was changed to 1.0 parts by mass. The content of the conductive particles was 1% by volume based on the total volume of the adhesive film.

### Example 3

An adhesive film was prepared as in Example 1, except that, regarding the second adhesive composition, the amount of 2,5-dimethyl-2,5-di(2-ethylhexanoylperoxy)hexane added, as a curing agent, was changed to 4.0 parts by mass, and the amount of dilauroyl peroxide added was changed to 2.0 parts by mass. The content of the conductive particles was 1% by volume based on the total volume of the adhesive film.

### Example 4

An adhesive film was prepared as in Example 1, except that, regarding the second adhesive composition, the amount of 2,5-dimethyl-2,5-di(2-ethylhexanoylperoxy)hexane added, as a curing agent, was changed to 3.5 parts by mass, and the amount of dilauroyl peroxide added was changed to 3.0 parts by mass. The content of the conductive particles was 1% by volume based on the total volume of the adhesive film.

### Example 5

An adhesive film was prepared as in Example 1, except that, regarding the second adhesive composition, the amount of 2,5-dimethyl-2,5-di(2-ethylhexanoylperoxy)hexane added, used as a curing agent, was changed to 3.0 parts by mass, and the amount of dilauroyl peroxide added was changed to 4.0 parts by mass. The content of the conductive particles was 1% by volume based on the total volume of the adhesive film.

### Example 6

An adhesive film was prepared as in Example 1, except that, regarding the second adhesive composition, the amount of 2,5-dimethyl-2,5-di(2-ethylhexanoylperoxy)hexane added, as a curing agent, was changed to 2.5 parts by mass, and the amount of dilauroyl peroxide added was changed to 5.0 parts by mass. The content of the conductive particles was 1% by volume based on the total volume of the adhesive film.

### (Cure Onset Temperature and Final Cure Temperature of Adhesive Film)

A DSC measurement was performed on each of the adhesive films (5 mg for each) of Comparative Example 1 and Examples 1 to 6, with a differential scanning calorimeter (DSC) (product name: DSC7, manufactured by Perkin Elmer, Inc.), under a nitrogen stream, under conditions including a heating rate of 10° C./min and a measurement temperature range of 40° C. to 250° C. The cure onset temperature (Tₒₙ) and the final cure temperature (T_{off}) were determined from the peak of the curing reaction in the obtained DSC curve. In addition, the difference between the cure onset temperature and the final cure temperature (T_{off}−Tₒₙ) was determined. The results are shown in Table 1.

### (Preparation of Electronic Members)

The following electronic members were prepared.

### Glass Member

A glass member including a glass substrate and Ti/Al/Ti wiring formed on the glass substrate was prepared. The glass substrate had a thickness of 0.7 mm, and the wiring of the glass member had a line width of 300 μm and an electrode height of 750 nm.

### Flexible Circuit Board (FPC)

An FPC including a resin film substrate and wiring provided on the resin film substrate was prepared; the resin film substrate included polyethylene terephthalate (PET) as a base material. The wiring of the FPC included an electrode made of a Cu layer with a pitch of 70 μm (spacing: 35 μm, electrode width: 35 μm, thickness: 18 μm), a Ni layer with a thickness of 0.5 μm, and a Au layer with a thickness of 2.5 μm, with the Ni layer and the Au layer being formed in this order on the Cu layer.

### (Fabrication of Connection Structure)

The adhesive film of Comparative Example 1 was placed on the glass member, and the FPC was placed on the adhesive film. Thus, a stack of the glass member, the adhesive film, and the FPC was fabricated. The placement was performed such that a main surface (surface on which the wiring was formed) of the glass substrate opposed a main surface (surface on which the wiring was formed) of the resin film. In addition, the placement was performed such that the first adhesive layer-side of the adhesive film was in contact with the glass member. A cushioning material made of silicone rubber was provided on the surface on the FPC-side of the fabricated stack, and heat and pressure were applied from above the cushioning material by using a thermocompression bonding machine (heating method: pulse heating, manufactured by Ohashi Engineering Co., Ltd.). Thus, a connection structure of Comparative Example 1, which included the glass member, a cured product of the adhesive film, and the FPC, was fabricated. The heating temperature was 120° C., the applied pressure was 14 MPa, and the heating time and the pressure application time were 30 seconds. As referred to herein, the heating temperature is a set temperature of the thermocompression bonding machine, and the applied pressure is a pressure per total connection area. Furthermore, connection structures of Examples 1 to 6 were fabricated with the respective adhesive films of Examples 1 to 6, in the same manner as described above.

### (Connection Resistance Between Electrodes)

A connection resistance of each of the connection structures of Comparative Example 1 and Examples 1 to 6 was investigated with a digital multimeter by using a four-terminal method. The connection resistance was that exhibited between the electrodes (between the electrodes of the glass member and the electrodes of the FPC) in a case where bonding was performed at a low temperature. The results are shown in Table 1.

### (Degree of Conversion)

Each of the connection structures of Comparative Example 1 and Examples 1 to 6 fabricated in the above-described manner was disassembled, and the cured product of the adhesive film was scraped off. Thus, evaluation samples of Comparative Example 1 and Examples 1 to 6, each weighing 5 mg, were prepared. Next, a measurement was performed on each of the evaluation samples of Comparative Example 1 and Examples 1 to 6, with a differential scanning calorimeter (DSC) (product name: DSC7, manufactured by Perkin Elmer, Inc.), under a nitrogen stream, at a heating rate of 10° C./min over a measurement temperature range of 30° C. to 250° C., to calculate a exothermic heat (J/g) of each of the evaluation samples. In addition, 5 mg of each of the adhesive films of Comparative Example 1 and Examples 1 to 6 was weighed and used as a control sample for each of the Comparative Example and Examples. A DSC measurement was performed on each of the control samples in the same manner as described above, to calculate the exothermic heat of the control samples. The degree of conversion was determined according to the equation shown below, for each of the Comparative Example and Examples. The results are shown in Table 1.

Degree of conversion (%)={1−(exothermic heat of evaluation sample/exothermic heat of control sample)}×100

TABLE 1

| | | | | Connection | Degree of |
|---|---|---|---|---|---|
| | | | | resistance | conversion |
| | T_{off} − Tₒₙ | Tₒₙ | T_{off} | (Ω) | (%) |
| Comparative | 22.0 | 81.0 | 103.0 | 1.00000 | 98 |
| Example 1 | | | | | |
| Example 1 | 8.1 | 100.4 | 108.5 | 0.70000 | 82 |
| Example 2 | 8.5 | 98.7 | 107.2 | 0.66775 | 87 |
| Example 3 | 10.3 | 94.9 | 105.2 | 0.63275 | 90 |
| Example 4 | 11.4 | 92.6 | 104.0 | 0.62000 | 92 |
| Example 5 | 13.7 | 89.7 | 103.4 | 0.56600 | 94 |
| Example 6 | 13.8 | 88.2 | 102.0 | 0.48800 | 98 |

### REFERENCE SIGNS LIST

1: adhesive film, 1A: first adhesive layer, 1B: second adhesive layer, 2, 2A, 2B: adhesive component, 3, 3A: conductive particles, 4: first electronic member, 5: second electronic member, 6: connection portion, 7: insulating material, 10: connection structure, 41: first substrate, 42: first electrode, 51: second substrate, 52: second electrode

1. An adhesive composition having a difference between a cure onset temperature and a final cure temperature of 20° C. or less.

2. The adhesive composition according to claim 1, wherein the final cure temperature is 130° C. or less.

3. The adhesive composition according to claim 1, wherein the cure onset temperature is 85° C. or more.

4. The adhesive composition according to claim 1, comprising a (meth)acrylate.

5. The adhesive composition according to claim 1, comprising conductive particles.

6. A connection structure comprising:
a first electronic member including a first electrode;
a second electronic member including a second electrode; and
a connection portion that is disposed between the first electronic member and the second electronic member and electrically connects the first electrode and the second electrode to each other, wherein
the connection portion comprises a cured product of the adhesive composition according to claim 5.

7. A method for producing a connection structure, the method comprising the steps of:
placing the adhesive composition according to claim 5 between a first electronic member and a second electronic member, the first electronic member including a first electrode, the second electronic member including a second electrode; and
thermocompression-bonding the first electronic member to the second electronic member with the adhesive composition interposed therebetween to electrically connect the first electrode and the second electrode to each other.

8. The producing method according to claim 7, wherein the thermocompression bonding is performed at 130° C. or less.
